(19) United States
(12) Patent Application Publication
(10) Pub. No.: US 2011/0240114 A1
(43) Pub. Date: Oct. 6, 2011

(54) METHOD OF FORMING A NEGATIVELY CHARGED PASSIVATION LAYER OVER A DIFFUSED P-TYPE REGION

(75) Inventors: Michael P. Stewart, San Francisco, CA (US); Mukul Agrawal, Sunnyvale, CA (US); Rohit Mishra, Santa Clara, CA (US); Hemant P. Mungekar, Campbell, CA (US); Timothy Weidman, Sunnyvale, CA (US)

(73) Assignee: Applied Materials, Inc., Santa Clara, CA (US)

(21) Appl. No.: 13/047,665

(22) Filed: Mar. 14, 2011

Related U.S. Application Data
(60) Provisional application No. 61/319,141, filed on Mar. 30, 2010.

(51) Int. Cl. H01L 31/0216; H01L 31/02; H01L 31/0248; H01L 31/0264; H01L 31/0376; H01L 31/18

(52) U.S. Cl. 136/256; 136/252; 136/258; 136/261; 438/73; 257/E31.001

(57) ABSTRACT

The present invention generally provides a method of forming a high quality passivation layer over a p-type doped region to form a high efficiency solar cell device. Embodiments of the present invention may be especially useful for preparing a surface of a boron doped region formed in a silicon substrate. In one embodiment, the methods include exposing a surface of the solar cell substrate to a plasma to clean and modify the physical, chemical and/or electrical characteristics of the surface and then deposit a charged dielectric layer and passivation layer thereon.

### CROSS-REFERENCE TO RELATED APPLICATIONS

This application claims benefit of U.S. Provisional Patent Application Ser. No. 61/319,141 [Attorney Docket #: APPM 14744L], entitled “Method of Forming A Negatively Charged Passivation Layer Over A Diffused P-Type Region,” filed Mar. 30, 2010, which is incorporated by reference herein.

### BACKGROUND OF THE INVENTION

1. Field of the Invention

Embodiments of the present invention generally relate to the fabrication of solar cells and particularly to a device structure and method of passivating a surface of a crystalline silicon solar cell.

2. Description of the Related Art

Solar cells are photovoltaic devices that convert sunlight directly into electrical power. The most common solar cell material is silicon (Si), which is in the form of single, polycrystalline or multi-crystalline substrates. Because the cost of electricity generated using silicon-based solar cells is higher than the cost of electricity generated by traditional methods, there has been an effort to reduce the cost of manufacturing solar cells that does not adversely affect the overall efficiency of the solar cell.

FIG. 1 schematically depicts a cross-sectional view of a standard silicon solar cell 100 fabricated from a crystalline silicon substrate 110. The substrate 110 includes a base region 101, an emitter region 102, a p-n junction region 103, a dielectric passivation layer 104, front electrical contact 107 and rear electrical contact 108. The p-n junction region 103 is disposed between base region 101 and emitter region 102 of the solar cell, and is the region in which electron-hole pairs are generated when solar cell 100 is illuminated by incident photons. Passivation layer 104 may act as an anti-reflective coating (ARC) layer for solar cell 100 as well as a passivation layer for the surface 105 of emitter region 102.

The efficiency of solar cell 100 may be enhanced by use of an antireflection coating (ARC) layer. When light passes from one medium to another, for example from air to glass, or from glass to silicon, some of the light may reflect off of the interface between the two media, even when the incident light is normal to the interface. The fraction of light reflected is a function of the difference in refractive index between the two media, wherein a greater difference in refractive index results in a higher fraction of light being reflected from the interface. An ARC layer disposed between the two media and having a refractive index value between the refractive indices of the two media is known to reduce the fraction of light reflected. Hence, the presence of an ARC layer on a light-receiving surface of solar cell 100, such as passivation layer 104 on surface 105, reduces the fraction of incident radiation reflected off of solar cell 100 and which, therefore, cannot be used to generate electrical energy.

When light falls on the solar cell, energy from the incident photons generates electron-hole pairs on both sides of p-n junction region 103. In a typical n-type emitter region 102 and p-type base region 101, electrons diffuse across the p-n junction to a lower energy level and holes diffuse in the opposite direction, creating a negative charge on the emitter and a corresponding positive charge build-up in the base. In an alternate configuration, which has a p-type emitter region 102 and n-type base region (e.g., reference numeral 101), electrons diffuse across the p-n junction to form a positive charge on the emitter and holes diffuse in the opposite direction to form a negative charge build-up in the base. In either case, when an electrical circuit is made between the emitter and the base, a current will flow and electricity is produced by solar cell 100. The efficiency at which solar cell 100 converts incident energy into electrical energy is affected by a number of factors, including the recombination rate of electrons and holes in solar cell 100 and the fraction of incident light that is reflected off of solar cell 100.

Recombination occurs when electrons and holes, which are moving in opposite directions in solar cell 100, combine with each other. Each time an electron-hole pair recombines in solar cell 100, charge carriers are eliminated, thereby reducing the efficiency of solar cell 100. Recombination may occur in the bulk silicon of substrate 110 or on either surface 105, 106 of substrate 110. In the bulk, recombination is a function of the number of defects in the bulk silicon. On the surfaces 105, 106 of substrate 110, recombination is a function of how many dangling bonds, i.e., unterminated chemical bonds, are present on surfaces 105, 106. Dangling bonds are found on surfaces 105, 106 because the silicon lattice of substrate 110 ends at these surfaces. These unterminated chemical bonds act as defect traps, which are in the energy band gap of silicon, and therefore are sites for recombination of electron-hole pairs.

As noted above, one function of the passivation layer 104 is to minimize the carrier recombination at the surface of the emitter region(s) 102 or the base region 101 over which the passivation layer 104 is formed. It has been found that forming a negative charge in a passivation layer 104 disposed over a p-type doped region formed in a solar cell device can help repel the carriers moving through the solar cell, and thus reduce the carrier recombination and improve the efficiency of the solar cell device. While it is relatively easy to form a passivation layer that has a net positive charge using traditional plasma processing techniques, it is difficult to form a stable negatively charged passivation layer on the surface of a silicon substrate.

Thorough passivation of the surface of a solar cell greatly improves the efficiency of the solar cell by reducing surface recombination. As used herein, “passivation” is defined as the chemical termination of dangling bonds present on the surface of a silicon lattice. In order to passivate a surface of solar cell 100, such as surface 105, a passivation layer 104 is typically formed thereon, thereby reducing the number of dangling bonds present on surface 105 by 3 or 4 orders of magnitude. For solar cell applications, passivation layer 104 is generally a silicon nitride (Si₃N₄, also abbreviated SiN) layer, and the majority of dangling bonds are terminated with silicon (Si) or nitrogen (N) atoms. But because silicon nitride (SiN) is an amorphous material, a perfect match-up between the silicon lattice of emitter region 102 and the amorphous structure of passivation layer 104 cannot occur. Hence, the number dangling bonds remaining on surface 105 after the formation of passivation layer 104 is still enough to reduce the efficiency of solar cell 100, requiring additional passivation of surface 105, such as hydrogen passivation. In the case of multi-crystalline silicon solar cells, hydrogen also helps to passivate the defect centers on the grain boundary.

Therefore, there is a need for an improved method of forming a passivation layer that has a desirable charge type and charge density at the surface of the solar cell device to minimize surface recombination of the charge carriers to improve the formed solar cell efficiency, and a passivation layer that has desirable optical and passivating properties.

### SUMMARY OF THE INVENTION

Embodiments of the present invention generally provide a method of forming a solar cell device, comprising forming a negative charge containing layer over a surface of a p-type doped region formed on a substrate, and forming a bulk layer on the negative charge containing layer. The negative charge containing layer that is formed over the p-type doped region is generally used to repel the electrons flowing in the solar cell device and passivate the surface to minimize carrier recombination and improve the efficiency of the formed solar cell device. While the ability of the negative charge containing layer to repel the electrons flowing through the adjacent p-type region, or “field” passivate the substrate surface, is important to reduce carrier recombination, a higher efficiency solar cell will also have a high quality passivation layer that has other optically beneficial properties and other passivating properties that generally improve the efficiency of the formed device. Therefore, in some configurations, the solar cell device may comprise one or more layers, or graded regions, that have differing material compositions, differing physical properties (e.g., mechanical and optical properties), and/or differing electrical properties to provide a desired passivating effect to the substrate surface.

Embodiments of the present invention may further provide a solar cell device, comprising one or more p-type doped regions formed in a surface of a solar cell substrate, a first layer disposed over the one or more p-type doped regions, and a bulk layer disposed over the first layer, wherein the bulk layer has a net positive charge.

Embodiments of the present invention may further provide a solar cell device, comprising one or more p-type doped regions formed in a surface of a solar cell substrate, a first layer having a negative charge disposed over the one or more p-type doped regions, and a bulk layer disposed over the first layer, wherein the bulk layer has a net positive charge. In some configurations, the amount of net negative charge present in the first layer can be greater than or equal to the amount of net positive charge in the bulk layer. In some configurations, the amount of net negative charge present in the first layer is adapted to achieve a charge density of greater than 1×10¹² Coulombs/cm² at the surface of the solar cell substrate.

Embodiments of the present invention may further provide a solar cell device, comprising one or more p-type doped regions formed in a surface of a solar cell substrate, a first layer disposed over the one or more p-type doped regions, wherein the first layer comprises fluorine or chlorine, and at least two elements selected from a list comprising oxygen, nitrogen, silicon and aluminum, and a bulk layer disposed over the first layer, wherein the bulk layer has a net positive charge and comprises silicon and nitrogen.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 schematically depicts a cross-sectional view of a conventional silicon solar cell fabricated from a single or multi-crystalline silicon wafer.

FIGS. 2A-2F depict cross-sectional views of a portion of a substrate corresponding to various stages of an embodiment of a process of the invention;

FIG. 3 depicts a process flow diagram of a passivation layer formation process performed on a silicon substrate in accordance with one embodiment of the invention;

FIG. 4 is a schematic side view of a parallel plate PECVD system that may be used to perform embodiments of the invention.

FIG. 5 is a top schematic view of one embodiment of a process system having a plurality of process chambers;

FIG. 6 depicts a process flow diagram of a passivation layer formation process performed on a silicon substrate in accordance with one embodiment of the invention.

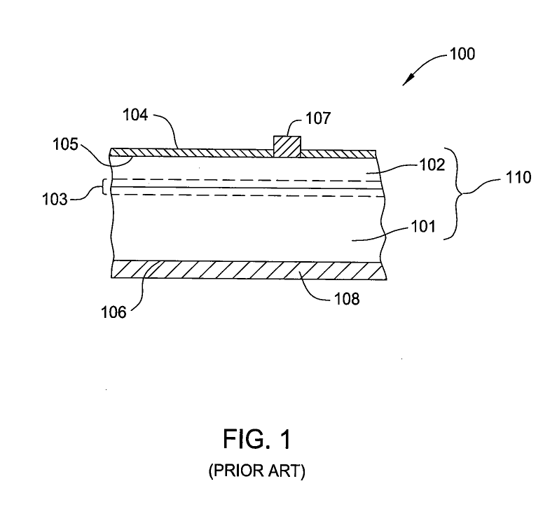

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present invention generally provides methods of forming high quality passivation layers over p-type doped regions to form high efficiency solar cell devices. Embodiments of the present invention may be especially useful for preparing a surface of a boron doped region formed in a silicon substrate. In one embodiment, the methods include exposing a surface of the solar cell substrate to a plasma to clean and modify the physical, chemical and/or electrical characteristics of the surface and then depositing a dielectric layer that contains an amount of charge and passivation layer thereon. Solar cell substrates that may benefit from the invention include substrates that have an active region that contains single crystal silicon, multi-crystalline silicon, and polycrystalline silicon, but may also be useful for substrates comprising germanium (Ge), gallium arsenide (GaAs), cadmium telluride (CdTe), cadmium sulfide (CdS), copper indium gallium selenide (CIGS), copper indium selenide (CuInSe₂), gallilium indium phosphide (GaInP₂), organic materials, as well as heterojunction cells, such as GaInP/GaAs/Ge or ZnSe/GaAs/Ge substrates, that are used to convert sunlight to electrical power.

Embodiments of the invention also generally provide methods of forming a negative charge containing passivation layer stack, or passivation layer structure, on one or more surfaces of a substrate, such as a surface of a doped p-type region. The negative charge containing layer that is formed over a p-type region is generally used to repel the electrons flowing in the solar cell device and passivate the surface to minimize carrier recombination and improve the efficiency of the formed solar cell device. While the ability of the negative charge containing passivation layer to repel the electrons flowing through the adjacent p-type region, or “field” passivate the substrate surface, is important to reduce carrier recombination, a high quality passivation layer needs to also have other optically beneficial properties and other passivating properties that generally improve the efficiency of a formed solar cell device. The additional passivation layer properties are often classified as the ability of the passivation layer to “surface” passivate the surface(s) it is disposed over, and “bulk” passivate the adjacent regions and surface of the substrate. The mechanism by which the passivation layer is able to perform these functions include, for example, the ability of a formed passivation layer to be a source of hydrogen (H⁺) that is used to correct defects in regions of the substrate, and the physical and/or chemical characteristics of the formed layer that are able to tie-up the dangling bonds found at the surface of the substrate.

In general, a passivation layer that is formed over a p-type region will have a desirable amount of formed negative charge disposed therein, have desirable optical properties to minimize light reflection, and will contain a desirable concentration of hydrogen to heal shallow defects found at the substrate surface. Typically, a passivation layer that has desirable optical properties will have an optical gradient, or gradient in the refractive index, across the formed region(s) of the passivation layer. Since silicon nitride is easy to form, has a refractive index that is between the refractive index of silicon (e.g., n=3.0) and glass (e.g., n=1.5) and is a stable film that is able to retain a desirable concentration of hydrogen, it is commonly the passivation layer material of choice. However, it is generally hard to form a silicon nitride (SiₓN_{y}) passivation layer that has a negative charge. Therefore, in one embodiment, the high quality passivation layer may comprise one or more layers, or graded regions, that have a differing composition, differing physical properties or differing electrical properties to provide a desired passivating effect.

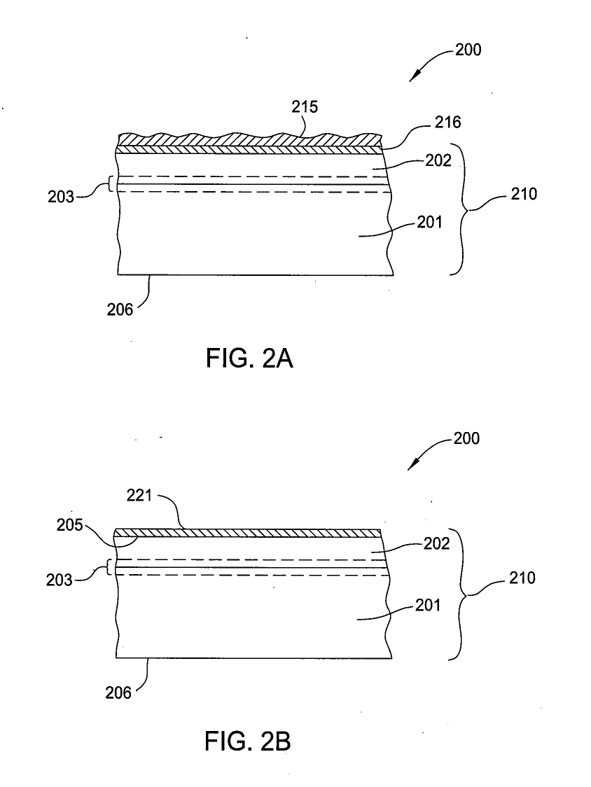

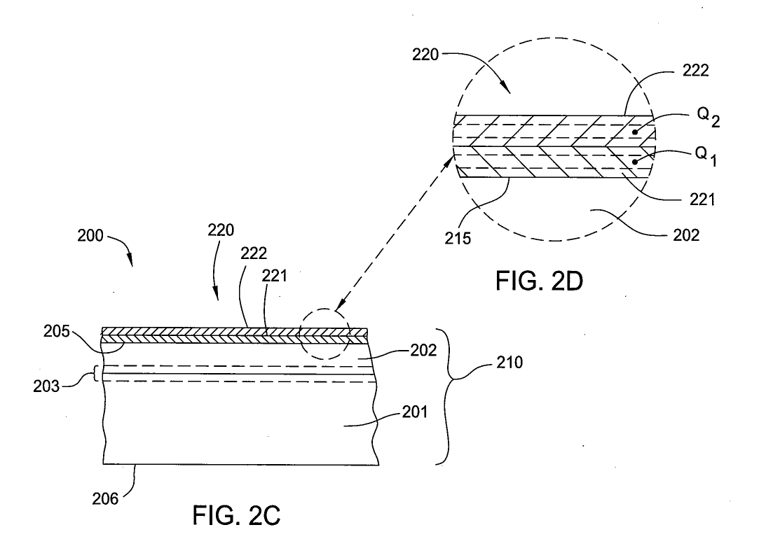

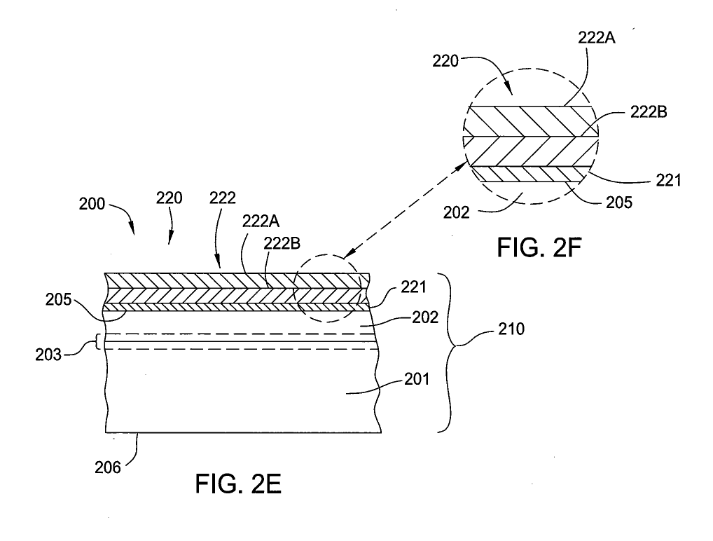

In one embodiment, as schematically illustrated in FIGS. 2C-2D, a passivation layer 220 formed over a surface 205 of p-type doped region comprises two layers that that have differing composition, physical properties and electrical properties that form a high quality passivation layer. In one embodiment, the passivation layer 220 comprises an interfacial layer 221 and a bulk layer 222. The interfacial layer may comprise a dielectric material that is configured to passivate the surface 205 of the p-type region, or in this case emitter region 202, and contains a desirable amount of trapped negative charge Q₁ to provide a desirable surface passivation of the p-type doped region. The bulk layer 222 may comprise a dielectric material that is configured to have desirable optical properties and passivate the surface 205 of the p-type region. In one embodiment, it is desirable to form a passivation layer 220 that has a net total amount of trapped negative charge (e.g., Coulombs) that can achieve a charge density of greater than about −1×10¹² Coulombs/cm². One will note that the negative sign in front of the charge density value is only intended to signify that the trapped charge in the layer is primarily negative versus positive.

In one embodiment, the bulk layer 222 comprises one or more silicon nitride layers that have a desirable index of refraction (n), absorption coefficient (k), film stress, and density. FIGS. 2E and 2F illustrate one embodiment of a bulk layer 222 that comprises a first passivation layer 222A and a second passivation layer 222B that each have differing composition, physical properties and/or electrical properties. In one example, the first passivation layer 222A and the second passivation layer 222B are silicon nitride layers that have at least one differing property. In general, a silicon nitride film formed using a plasma enhanced chemical vapor deposition (PECVD) technique or physical vapor deposition (PVD) technique will have a refractive index of between about 1.9 and about 2.15 and have a trapped positive charge Q₂ (FIG. 2D). The presence of a trapped “positive” charge Q₂ in the passivation layer 220 will tend to attract the electrons moving through the solar cell device causing diversion of the mobile carriers and/or unwanted recombination of the carriers, and thus reducing the efficiency of the solar cell device.

Therefore, in one embodiment of the passivation layer 220, the total amount of the trapped negative charge Q₁ in the interface layer 221 is greater than the total amount of the positive trapped charge Q₂ in the bulk layer 222, so that the net trapped negative charge Q₁ can counteract the effects of the net stored trapped positive charge Q₂ in the bulk layer 222. In one embodiment, the sum of the total amount of the trapped negative charge Q₁ and total amount of the positive trapped charge Q₂ found in the passivation layer 220 has enough trapped charge to achieve an interfacial charge density greater than about −1×10¹² Coulombs/cm². In one example, the passivation layer 220 has enough trapped charge to achieve an interfacial charge density between about −1×10¹² Coulombs/cm² and about −1×10¹⁴ Coulombs/cm², such as between about −2×10¹² Coulombs/cm² and −4×10¹³ Coulombs/cm². One will note that the negative sign in front of the desired charge density number is only intended to signify that the charge seen by the surface 205 is negative versus positive, and thus the absolute value of Q₁ is greater than the absolute value of Q₂. In another embodiment, the sum of the total amount of the trapped negative charge Q₁ and total amount of the positive trapped charge Q₂ found in the passivation layer 220 is about zero (i.e., |Q₁| equals |Q₂|). In this case, the affect of the positive trapped charge Q₂ seen at the surface 205 has at least been minimized, but no repelling effect of the trapped negative charge will generally be seen by the electrons at or below the surface 205. In cases where the interface layer 221 and the bulk layer 222 each both have positive and negative charges in them, the values of Q₁ and Q₂ discussed herein, and affecting the carriers in the substrate, are the net values of charge, or the sum of the absolute value of the total amount of positive charge minus the absolute value of the total amount negative charge taken in each respective layer. In yet another embodiment, where the electron repelling effect of the passivation layer 220 is not important, but it is important to assure that all of the trapped positive charge is at a minimum compensated for, it may be desirable for the sum of the total amount of the trapped negative charge Q₁ and total amount of the positive trapped charge Q₂ found in the passivation layer 220 have enough trapped charge to achieve an interfacial charge density between about 0 and about −1×10¹⁴ Coulombs/cm². In some embodiments, it is desirable to position the bulk of the trapped negative charge Q₁ a 100 angstroms (Å) or less from the surface 205 to assure that the trapped charge will have a desirable field strength to repel the electrons at or below the surface 205, since the ability to repel the electrons will vary with the one over the square of the distance (1/d²) between trapped negative charge Q₁ and the electron(s).

One advantage of a passivation layer 220 structure having an interfacial layer 221 positioned between the surface 205 and the bulk layer 222 is that the electric field created by the positive charge formed in the bulk layer 222 is reduced by the separation of the bulk layer 222 from the surface 205. One will note that the electric field (E) strength is inversely proportional to the square of the distance between the surface 205 and the bulk layer 222, and thus the farther the bulk layer 222 is away from the surface 205, the less of an affect it will have on the mobile carriers flowing through the solar cell device. Therefore, in one embodiment, the interface layer 221 has a desirable thickness that is used to reduce the affect of the positive charge found in the bulk layer 222. In one example, the interface layer 221 is a dielectric layer that is between about 50 Angstroms (Å) and about 800 Å thick. In one embodiment, when the passivation layer 220 is disposed over a p-type light receiving surface of a substrate (e.g., emitter region 202), such as surface 205, the interface layer 221 is a dielectric layer that is between about 50 Angstroms (Å) and about 200 Å thick. In one embodiment, when the passivation layer 220 is disposed over a rear surface of a p-type substrate (e.g., base region 201), such as surface 206, the interface layer 221 is a dielectric layer that is between about 500 Angstroms (Å) and about 800 Å thick. In one embodiment, the thickness of the interface layer 221 is adjusted to compensate for a given process recipe's ability to create trapped negative charge Q₁ in the interface layer 221, and thus control the affect of the trapped positive charge Q₂ formed in the bulk layer 222 on the p-type doped region below the surface 205. In one example, even if the amount of trapped negative charge Q₁ in the formed interface layer 221 is negligible, by spacing a positively charged bulk layer 222 a distance away from the surface 205, the field created by the positive charge at the surface 205 will be reduced and thus improve the efficiency of the solar cell.

### Passivation Layer Formation Process

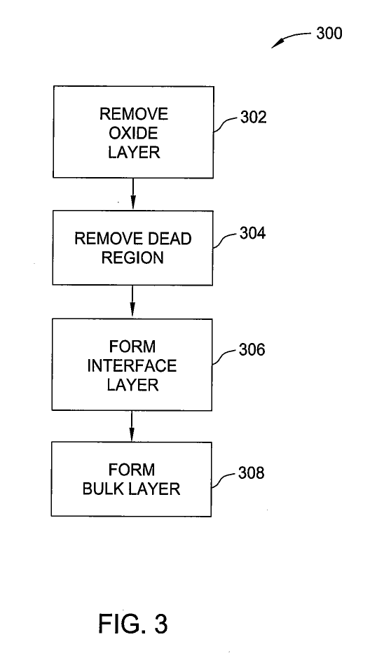

FIGS. 2A-2F illustrate schematic cross-sectional views of a solar cell substrate 210 during different stages in a processing sequence used to form the passivation layer 220 on a surface (e.g., surface 205) of a solar cell 200. FIG. 3 illustrates a process sequence 300 used to form the passivation layer on a solar cell substrate 210. The sequences found in FIG. 3 correspond to the stages depicted in FIGS. 2A-2F, which are discussed herein. In one embodiment of the solar cell 200, the base region 201 comprises an n-type crystalline silicon substrate (e.g., reference numeral 201), and the emitter region 202 comprises a p-type layer formed over the base region 201. While the discussion below primarily discusses a method and apparatus for processing a substrate having a p-type emitter region formed over an n-type base region, this configuration is not intended to limit the scope of the invention described herein, since the passivation layer could also be formed over a p-type base region solar cell configuration.

FIG. 2A schematically illustrates a cross-sectional view of an at least partially formed silicon solar cell 200 that comprises a substrate 210. The substrate 210 includes a base region 201, an emitter region 202, and a p-n junction region 203. The p-n junction region 203 is disposed between base region 201 and emitter region 202 of the solar cell, and is the region in which electron-hole pairs are generated when solar cell 200 is illuminated by incident photons of light.

However, during normal processing of a solar cell device, a thin and generally poor quality native oxide layer 215 will form on one or more of the surfaces of the substrate 210. In configurations where the native oxide layer 215 is formed over a p-type boron doped region, the oxide layer 215 may comprise a boron silicate glass (BSG) containing layer. In one example, the BSG containing oxide layer is formed over a p-type emitter region(s) 202 formed over a n-type base region 201 (FIG. 2A). In an alternate example, the BSG type oxide layer is formed over the surface 206 on the back side of a p-type substrate base region 201. The thickness and density of the formed oxide layer 215 will depend on how the layer was formed, since in some cases the oxide layer may be formed during or after one or more thermal processing steps, such as a furnace anneal step that is used to “drive-in” dopants or anneal one or more layers formed on the substrate 210. In some cases the oxide layer may be formed by extended exposure to air.

Further, it is common for a partially formed solar cell device to also have a dead region 216, which contains a high concentration of dopant atoms, formed at the interface between the oxide layer 215 and the surface of the substrate 210. The high dopant concentration in the dead region 216 is believed to be created by the diffusion of dopant atoms to the surface 205 of the substrate 210 during prior doping or thermal processing steps. In one example, the dead region 216 contains a high concentration of boron atoms (e.g., >0.1 atomic %) at the surface of a silicon containing p-type doped emitter region 202. In one embodiment, the dead region 216 has a doping concentration high enough to form a region that has a sheet resistance of less than about 50 Ohms per square (Ω/□). In general, it is hard to remove these boron doped layers using conventional processing techniques, which may include wet chemical etching processes. However, it is generally important to form a clean substrate surface to prevent contamination of the solar cell substrate during subsequent processing and improve the passivating effect of the dielectric passivation layer formed over the doped surface.

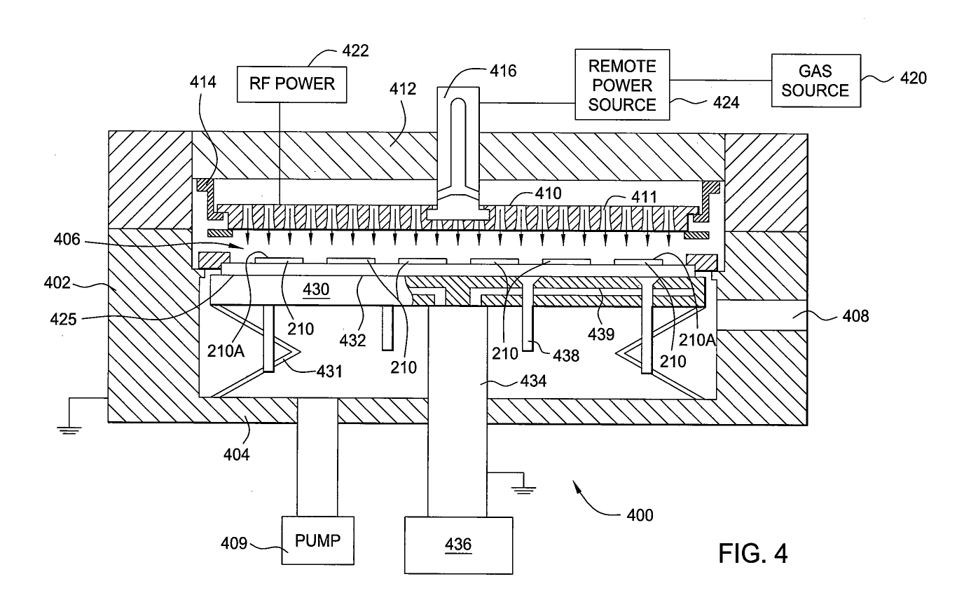

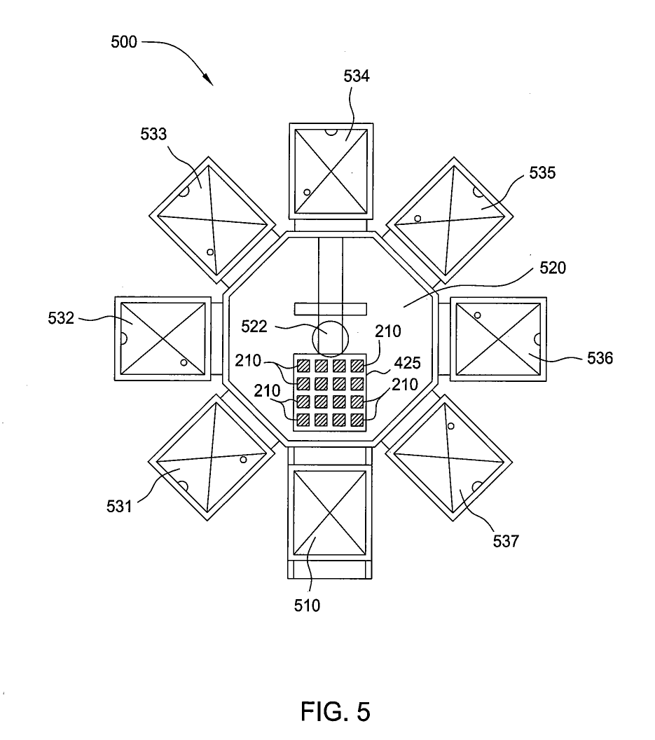

Referring to FIG. 3, the process sequence 300 used to form the passivation layer on a solar cell substrate 210 generally begins at box 302. At box 302, the surfaces of the substrate 210 are cleaned to remove the oxide layer 215 (FIG. 2A) formed on the surfaces of the substrate. The processes performed at box 302 may be performed in a single processing step performed in one substrate processing chamber, or as multiple separate process steps performed in one or more substrate processing chambers. In one embodiment, the clean process at box 302 may be performed using a dry cleaning process in which the substrate 210 is exposed to a reactive plasma etching process to remove the oxide layer 215. An example of a dry cleaning process and dry processing chamber are further described below in conjunction with FIGS. 4 and 5.

In one embodiment, at box 302, after disposing one or more of the substrates 210 in a process chamber, such as chamber 400 in FIG. 4, the oxide layer 215 is exposed to a reactive gas to form a thin film (not shown) on the oxide layer 215. The reactive gas may comprise nitrogen, fluorine, and/or hydrogen. In some embodiments, the reactive gas comprises radicals and/or ions containing nitrogen, fluorine, chlorine or combinations thereof, and is provided to the process chamber having the substrate disposed therein and directed toward the substrate. The thin film generally comprises a solid compound formed by reaction of the radicals with oxygen from the oxide layer 215. An exemplary reactive cleaning process for removing native oxides on a surface of the substrate using an ammonia (NH₃) and nitrogen trifluoride (NF₃) gas mixture performed within a processing chamber will now be described. The reactive cleaning process begins by placing a substrate into a processing chamber. During processing, the substrate may be cooled below about 65° C., such as between about 15° C. and about 50° C.

Next, during one part of the process performed at box 302, the thin film formed on the oxide layer 215 is thermally treated to remove it from the surface of the substrate. In some embodiments, the thermal treatment may be an annealing process performed in the processing chamber 400, or another adjacent chamber found in the system 500. During this step the thin film sublimes away from the substrate surface, taking oxygen and other impurities, and leaving a hydrogen-terminated layer (not shown) behind. In some embodiments, the hydrogen-terminated layer may also have traces of fluorine atoms in the formed hydrogen-terminated layer.

Next, at box 304, the dead region 216 is removed from the surfaces of the substrate 210 by use of a dry cleaning process. In one embodiment, after removing oxide layer 215 from a surface of the substrate 210 the substrate is then delivered to a dry processing chamber to remove the dead region 216. In general, the dry cleaning process performed at box 304 generally includes exposing the dead region 216 to an RF plasma for a desired period of time to etch and remove the dead regions from the exposed substrate surface. An example of such a dry processing chamber and dry cleaning process is further described below in conjunction with FIGS. 4 and 5. One will note that in some cases, it may be desirable to assure that the substrate is not exposed to oxygen for extended periods of time after performing the cleaning process 303 before the cleaning process is performed on the substrate at box 304 to prevent the re-oxidation of the cleaned surface. Therefore, in some embodiments of the invention, it is desirable to perform all of the process in boxes 302-308 in an oxygen-free inert and/or vacuum environment, such as in the vacuum processing regions of a cluster tool, or system 500 (FIG. 5), so that the substrate is not exposed to oxygen between the process steps.

Next, at box 306, as shown in FIGS. 2B and 3, an interface layer 221 is formed on the surface 205 of the substrate. In one embodiment, the interface layer 221 is a dielectric layer that comprises a material selected from the group of silicon oxide (SiₓO_{y}), silicon oxynitride (SiON), silicon oxycarbonnitride (SiOCN), silicon oxycarbide (SiOC), titanium oxide (TiₓO_{y}), tantalum oxide (TaₓO_{y}), lanthanum oxide (LaₓO_{y}), Hafnium oxide (HfₓO_{y}), titanium nitride (TiₓN_{y}), tantalum nitride (TaₓN_{y}), hafnium nitride (HfN), hafnium oxynitride (HfON), lanthanum nitride (LaN), lanthanum oxynitride (LaON), chlorinated silicon nitride (SiₓN_{y}:Cl), chlorinated silicon oxide (SiₓO_{y}:Cl), amorphous silicon, amorphous silicon carbide and/or aluminum oxide (Al₂O₃). In another embodiment, the interface layer 221 is a dielectric layer that comprises a material selected from the group of fluorinated silicon oxide (SiₓO_{y}:F) and fluorinated silicon nitride (SiₓN_{y}:F). In one example, as noted above, the interface layer 221 may be between about 50 Angstroms (Å) and about 800 Å thick. In one embodiment, the interface layer 221 is formed over the surface 205 using a chemical vapor deposition (PECVD) or physical vapor deposition (PVD) technique. An example of an interface layer 221 formation process is further described below in conjunction with FIGS. 4 and 5.

Next, at box 308, as shown in FIGS. 2C-2D and 3, a bulk layer 222 is formed on the interface layer 221 using a plasma enhanced chemical vapor deposition (PECVD) process. In one embodiment, the bulk layer 222 comprises a plurality of passivation layers, such as passivation layers 222A and 222B (FIGS. 2E-2F), which are used to passivate the surface of the substrate. In one embodiment, the bulk layer 222 comprises a thin passivation and/or antireflection layer that comprises silicon oxide, silicon nitride, amorphous silicon, amorphous silicon carbide and/or aluminum oxide (Al₂O₃). In one embodiment, a silicon nitride (SiN) passivation and antireflection layer, or thin amorphous silicon (a-Si:H) layer or amorphous silicon carbide (a-SiC:H) layer and silicon nitride (SiN) stack is formed over the surface 205 using a chemical vapor deposition (PECVD) technique on multiple solar cell substrates supported on a suitable large area substrate carrier. In one embodiment, the passivation layer 220 may comprise an intrinsic amorphous silicon (i-a-Si:H) layer and/or p-type amorphous silicon (p-type a-Si:H) layer stack followed by a transparent conductive oxide (TCO) layer and/or an ARC layer (e.g., silicon nitride), which can be deposited by use of a physical vapor deposition process (PVD) or chemical vapor deposition process (e.g., PECVD). The formed stack is generally configured to generate a front surface field effect to reduce surface recombination and promote lateral transport of electron carriers to nearby doped contacts formed on the substrate. An example of a passivation layer formation process is further described below.

In one embodiment of the process sequence 300, after performing the processes in box 304, but before performing the processes at box 306, the surface 205 of the substrate 210 is exposed to a reactive gas containing RF plasma that is used to form a supplementary negatively charged layer that is positioned between the surface 205 and the interface layer 221 using an RF plasma processing step. In one embodiment, the supplementary negatively charged layer comprises a fluorine (F) rich, and/or chlorine (Cl) rich, layer that is less than about 50 Angstroms (Å) thick. It is believed that by exposing the surface 205 directly to a plasma containing ionized fluorine, and/or ionized chlorine, the exposed surface can be “doped”, “stuffed” or covered with a fluorine rich, or chlorine rich, layer that has a negative charge. In one embodiment, it is desirable for the supplementary negatively charged layer, which is formed on a silicon containing surface, to have a negative charge density greater than about −1×10¹² Coulombs/cm². While the deposited charged layer will generally contain a desirable charge density, the charged layer also needs to be physically, chemically and electrically stable enough to allow the interface layer 221 to be formed thereon without significantly degrading the properties of the formed charged layer.

### Hardware Configuration

FIG. 4 is a schematic cross-section view of one embodiment of a plasma enhanced chemical vapor deposition (PECVD) chamber 400 in which one or more of the processes illustrated and discussed in conjunction with FIG. 3 may be performed. A similarly configured plasma enhanced chemical vapor deposition chamber is available from Applied Materials, Inc., located in Santa Clara, Calif. It is contemplated that other deposition chambers, including those from other manufacturers, may be utilized to practice the present invention.

It is believed that the plasma processing configuration provided in the processing chamber 400 has significant advantages over other prior art configurations when used to perform one or more of the processes described in FIG. 3. In one embodiment, the PECVD chamber 400 is configured to process a plurality of substrates at one time. In one embodiment, the plasma enhanced chemical vapor deposition (PECVD) process chamber 400 is adapted to simultaneously process a plurality of substrates that are arranged in a planar array arrangement (FIG. 5), as opposed to processing vertical stacks of substrates (e.g., batches of substrates stacked in cassettes). Processing the batches of substrates arranged in a planar array allows each of the substrates in the batch to be directly and uniformly exposed to the generated plasma, radiant heat, and/or processing gases. Therefore, each substrate in the planar array is similarly processed in the processing region of a processing chamber, and thus does not rely on diffusion type processes and/or the serial transfer of energy to all substrates in a conventionally configured batch that is being processed, such as a stacked or back-to-back configured batch of substrates commonly found in the prior art.

In one configuration, the PECVD chamber 400 is adapted to accept a substrate carrier 425 (FIGS. 4 and 5) that is configured to hold a batch of substrates during the transferring and substrate processing steps. In one embodiment, the substrate carrier 425 has a surface area of about 10,000 cm² or more, preferably about 40,000 cm² or more, and more preferably about 55,000 cm² or more that is configured to support a planar array of substrates disposed thereon during processing. In one embodiment, the substrate carrier 425 has a plurality of recesses (not shown) formed therein that are adapted to hold between about 4 and about 49 solar cell substrates that are 156 mm×156 mm×0.3 mm in size in a face-up or face-down configuration. The substrate carrier 425 may be formed from a ceramic (e.g., silicon carbide, alumina), graphite, metal or other suitable material. In one configuration, a batch of solar cell substrates are simultaneously transferred in a vacuum or inert environment (e.g., transfer chamber 520 in FIG. 5) on the carrier 425, between a plurality of processing chambers to reduce the chance of contamination and improve substrate throughput over other prior art configurations.

The chamber 400 generally includes walls 402, a bottom 404, and a showerhead 410, and substrate support 430 which define a process volume 406. The process volume is accessed through a valve 408 such that the substrates disposed on the substrate carrier 425, may be transferred in and out of the chamber 400. The substrate support 430 includes a substrate receiving surface 432 for supporting a substrate and stem 434 coupled to a lift system 436 to raise and lower the substrate support 430. A shadow from 433 may be optionally placed over periphery of the substrate carrier 425. Lift pins 438 are moveably disposed through the substrate support 430 to move the substrate carrier 425 to and from the substrate receiving surface 432. The substrate support 430 may also include an embedded heating and/or cooling elements 439 to maintain the substrate support 430 at a desired temperature. The substrate support 430 may also include grounding straps 431 to provide RF grounding at the periphery of the substrate support 430. Examples of grounding straps are disclosed in U.S. Pat. No. 6,024,044 issued on Feb. 15, 2000 to Law et al. and U.S. patent application Ser. No. 11/613,934 filed on Dec. 20, 2006 to Park et al., which are both incorporated by reference in their entirety to the extent not inconsistent with the present disclosure. In one embodiment, the substrate support 430 has an RF source (not shown) that is coupled to an electrode (e.g., reference numeral 439) that is embedded in the substrate support 430 so that an RF bias can be applied to the substrates 210 disposed over the substrate support 430.

The showerhead 410 is coupled to a backing plate 412 at its periphery by a suspension 414. The showerhead 410 may also be coupled to the backing plate by one or more center supports 416 to help prevent sag and/or control the straightness/curvature of the showerhead 410. A gas source 420 is coupled to the backing plate 412 to provide gas through the backing plate 412 and through the holes 411 in the showerhead 410 to the substrate receiving surface 432. A vacuum pump 409 is coupled to the chamber 400 to control the process volume 406 at a desired pressure. An RF power source 422 is coupled to the backing plate 412 and/or to the showerhead 410 to provide a RF power to the showerhead 410 so that an electric field is created between the showerhead and the substrate support so that a capacitively coupled plasma may be generated using the gases disposed between the showerhead 410 and the substrate support 430. Various RF frequencies may be used, such as a frequency between about 0.3 MHz and about 200 MHz. In one embodiment the RF power source is provided at a frequency of 13.56 MHz to a showerhead (i.e., electrode). Examples of showerheads are disclosed in U.S. Pat. No. 6,477,980 issued on Nov. 12, 2002 to White et al., U.S. Publication 20050251990 published on Nov. 17, 2006 to Choi et al., and U.S. Publication 2006/0060138 published on Mar. 23, 2006 to Keller et al, which are all incorporated by reference in their entirety to the extent not inconsistent with the present disclosure. It is believed that the direct contact of the capacitively coupled plasma to the processing surface 210A (FIG. 4) of the substrates 210 has advantages over designs that do not directly expose all of the substrates to the plasma, due to the ability of the chamber 400 configuration to provide energetic and/or ionized species directly to all parts of the processing surface 210A during processing. The degree of plasma interaction applied to the complete processing surface 210A can be directly controlled in the chamber 400 by adjusting the RF power delivered to the showerhead 410, the chamber pressure during processing, and/or the bias applied to the substrate support 430. Typical non-direct exposure type chamber configurations include remotely driven plasma configurations or other stacked wafer configurations that rely on the diffusion of the generated plasma to one or more of the substrates, or parts of each of the substrates, during processing.

However, in some embodiments, a remote plasma source 424, such as an inductively coupled remote plasma source, may also be coupled between the gas source and the backing plate. In one process configuration, between processing substrates, a cleaning gas may be provided to the remote plasma source 424 so that a remote plasma is generated and provided to clean chamber components. The cleaning gas may be further excited by the RF power source 422 provided to the showerhead. Suitable cleaning gases include but are not limited to NF₃, F₂, and SF₆. Examples of remote plasma sources are disclosed in U.S. Pat. No. 5,788,778 issued Aug. 4, 1998 to Shang et al, which is incorporated by reference to the extent not inconsistent with the present disclosure.

In one embodiment, the heating and/or cooling elements 439 may be set to provide a substrate support temperature during deposition of about 400° C. or less, preferably between about 100° C. and about 400° C., more preferably between about 150° C. and about 300° C., such as about 200° C. The spacing during deposition between the top surface of a substrate disposed on a substrate carrier 425 disposed on the substrate receiving surface 432 and the showerhead 410 may be between 400 mil and about 1,200 mil, preferably between 400 mil and about 800 mil.

FIG. 5 is a top schematic view of one embodiment of a process system 500 having a plurality of process chambers 531-537, such as PECVD chambers chamber 400 of FIG. 4 or other suitable chambers capable of performing the processes described in conjunction with FIG. 3. The process system 500 includes a transfer chamber 520 coupled to a load lock chamber 510 and the process chambers 531-537. The load lock chamber 510 allows substrates to be transferred between the ambient environment outside the system and vacuum environment within the transfer chamber 520 and process chambers 531-537. The load lock chamber 510 includes one or more evacuatable regions that is configured to hold one or more substrate carriers 425 that are configured to support a plurality of substrates 210. The evacuatable regions are pumped down during the input of the substrates into the system 500 and are vented during the output of the substrates from the system 500. The transfer chamber 520 has at least one vacuum robot 522 disposed therein that is adapted to transfer the substrate carriers 425 and substrates between the load lock chamber 510 and the process chambers 531-537. Seven process chambers are shown in FIG. 5; however, the system 500 may have any suitable number of process chambers.

In one embodiment of system 500, a first processing chamber 531 is configured to perform the processes within box 302, a second process chamber 532 is configured to perform the processes within box 304, a third process chamber 533 is configured to perform the processes within box 306, and a fourth process chamber is configured to perform the processes within box 308 on the substrates. In another embodiment of system 500, a first processing chamber 531 is configured to perform the first clean processes at boxes 302 and 304, a second process chamber 532 is configured to perform the process within box 306, and a third process chamber 533 is configured to perform process within box 308 on the substrates. In yet another embodiment of system 500, a first processing chamber 531 is configured to perform the process(es) within boxes 302 and 304, and a second process chamber 532 is configured to perform the process(es) within boxes 306 and 308 on the substrates. In yet another embodiment of system 500, at least one of the process chambers 531-537 is configured to perform all of the processes, such as boxes 302, 303, 304, 306 and 308, on the substrates.

### Passivation Layer Formation Processes

Referring back to FIG. 3, during one phase of the process sequence 300 the surfaces of the substrate 210 are subjected to a plurality of processing steps that are used to form the interface layer 221 and bulk layer 222 on the surfaces of the substrate. The following are illustrative examples of processes performed at boxes 306-308 that may be performed in a processing chamber similar to process chamber 400, which is discussed above. The processes described below generally include methods of preparing a surface of a substrate using primarily dry processing techniques performed in one or more process chambers (e.g., process chamber 400) found in one or more cluster tools, such as systems 500. In one embodiment, all of the processes performed in the process sequence 300 are performed in one or more of the processing chambers 531-537 found in one or more systems 500. One will note that the hardware configurations illustrated in FIGS. 4 and 5 are not intended to be limiting as to the scope of the invention described herein.

As noted above, due to exposure of the surface 205 to oxygen and/or the act of performing various high temperature processing steps on the substrate 210, an oxide layer 215 and a dead region 216 may be formed on the surface 205. In many embodiments, this will occur after formation of the last layer of a solar cell junction, such as a p-type or n-type doped layer. In other embodiments, this will occur prior to forming one or more conductor layers, such as after a heavily doped, or degeneratively doped, p-type layer is formed. It should be noted that while the various embodiment of the invention described herein are discussed in relation to cleaning a surface of a deposited layer, such as the emitter region 202, this configuration is not intended to limit the scope of the invention, since the apparatus and cleaning process(es) described herein can be used during any phase of the solar formation process without deviating from the basic scope of the invention described herein.

In one embodiment, after performing the processes at boxes 302-304 on a batch of substrates 210 that are disposed on a substrate carrier 425, the substrates are then positioned in a processing chamber so that the processes performed at box 306 can be performed on the substrates. In one embodiment, at box 306, the substrate is exposed to a precursor containing gas and RF plasma to form an interface layer 221 on the exposed surfaces of the substrates. In one example, the substrate is exposed to a 13.56 MHz RF plasma that contains an amount of a precursor gas that is used to form a dielectric film, which comprises silicon oxide (SiₓO_{y}), silicon oxynitride (SiON), silicon oxycarbonnitride (SiOCN), silicon oxycarbide (SiOC), titanium oxide (TiₓO_{y}), tantalum oxide (TaₓO_{y}), lanthanum oxide (LaₓO_{y}), hafnium oxide (HfₓO_{y}), titanium nitride (TiₓN_{y}), tantalum nitride (TaₓN_{y}), hafnium nitride (HfN), hafnium oxynitride (HfON), lanthanum nitride (LaN), lanthanum oxynitride (LaON), chlorinated silicon nitride (SiₓN_{y}:Cl), chlorinated silicon oxide (SiₓO_{y}:Cl), amorphous silicon, amorphous silicon carbide and/or aluminum oxide (Al₂O₃). In another example, the substrate is exposed to a 13.56 MHz RF plasma that contains an amount of a precursor gas that is used to form a dielectric film, which comprises fluorinated silicon oxide (SiₓO_{y}:F) and fluorinated silicon nitride (SiₓN_{y}:F). In one example, the precursor gas is a mixture of gases comprising silane (SiH₄), nitrogen (N₂), or ammonia (NH₃), and fluorine (F₂).

In one embodiment, the interface layer 221 comprises a silicon oxide film, such as a SNOW™ silicon oxide film layer available from Applied Materials Inc, of Santa Clara, Calif. In general, the SNOW™ film layer formation process comprises depositing of a film by exposing the surface 205 to a silicon-containing precursor simultaneously with an RF plasma. The silicon-containing precursor can include octamethyl-cyclotetrasiloxane (OMCTS), methyldiethoxysilane (MDEOS), bis(tertiary-butylamino)silane (BTBAS), tridimethylaminosilane (TriDMAS), silane, disilane, dichlorosilane, trichlorosilane, dibromosilane, silicon tetrachloride, silicon tetrabromide, or combinations thereof. In one aspect, OMCTS and silane are preferred silicon-containing precursors. Gases that are optionally introduced into the chamber at the same time as the silicon-containing precursor include carrier gases, such as helium, nitrogen, oxygen, nitrous oxide, and argon. Oxygen and/or helium are the preferred additional gases for introduction to the chamber if an additional gas is used. In one example, the SNOW™ silicon oxide layer is formed by, first, delivering a silicon-containing precursor and a carrier gas (e.g., helium) into the chamber at a desired flow rate to achieve a chamber pressure greater than about 5 mTorr, such as between about 1.8 Torr and about 10 Torr. The ratio of the flow rate of the silicon-containing precursor, e.g., octamethylcyclotetrasiloxane, to the flow rate of the carrier gas, e.g., helium, into the chamber is between about 1:1 and about 1:100. In one case, the temperature of a substrate support 430 positioned in the process chamber 400 may be between about 200° C. and about 400° C. The silicon-containing precursor may be delivered into the chamber for a period of time sufficient to deposit a layer having a thickness of between about 50 Å and about 800 Å. The plasma may be formed by delivering RF power at between about 3000 W and about 12,000 W at a frequency of between about 40 kHz and 100 MHz, such as about 13.56 MHz. The RF power may be provided to the showerhead 410 and/or a substrate support 430. Next, an oxygen plasma treatment is performed on the deposited layer to generate a layer of silicon oxide. The oxygen-containing gas, such as oxygen or nitrous oxide, may be introduced into the chamber at a flow rate to achieve a chamber pressure of between about 500 mTorr and about 10 Torr. The oxygen-containing gas may be delivered into the chamber for a period of time such as between about 0.1 seconds and about 120 seconds. The oxygen plasma may be formed by applying an RF power of between about 50 W and about 3000 W in the chamber at a frequency of between about 40 kHz and 100 MHz, such as about 13.56 MHz. The temperature of the substrates are maintained at a temperature between about 175° C. and about 500° C., while the oxygen-containing gas is flowed into the chamber.

In one embodiment of the silicon oxide film formation process, the silicon-containing precursor deposition step and oxygen plasma treatment step are performed simultaneously on the substrate to form a layer having desirable physical and charge containing properties. In this combined process step, a silicon-containing precursor and an oxygen-containing gas are both delivered into the processing region of the processing chamber while an RF plasma is formed in the processing chamber for a period of time sufficient to deposit a layer having a desired thickness, such as between about 50 Å and about 800 Å. In one example, the RF plasma may be formed by delivering RF power at between about 3000 W and about 12,000 W at a frequency of about 13.56 MHz, while an OMCTS precursor and oxygen gas are delivered into the processing region of the chamber. The temperature of the substrates are maintained at a temperature between about 175° C. and about 500° C., while the oxygen-containing gas is flowed into the chamber.

In another embodiment of a process performed at box 306, the interface layer 221 film layer formation process comprises depositing a fluorinated or chlorinated silicon nitride containing film layer. In one embodiment, process includes introducing a precursor gas mixture comprising silane (SiH₄), nitrogen (N₂) and fluorine (F₂) or chlorine (Cl₂). In one example, flow rates for a process gas mixture containing silane, ammonia, fluorine and hydrogen may be 3.5 sccm, 50 sccm, 5 sccm and 80 sccm, per liter of chamber volume, respectively, to achieve a chamber pressure of 1.5 Torr, while an RF power of 0.74 W/cm² at a frequency of 13.56 MHz is applied to the showerhead 410 to generate a plasma for a period of time of about 9 seconds. The substrate support 430 temperature is generally maintained at a temperature of about 390° C. during this process step.

In another embodiment of a process performed at box 306, the interface layer 221 film layer formation process comprises depositing a silicon oxide containing film layer using a rapid thermal oxidation process. In one embodiment, process includes introducing an oxygen containing gas and heating the substrates to a temperature of greater than about 800° C. for about 0.5 and about 5 seconds. In one embodiment, a fluorine (F₂) or a chlorine (Cl₂) containing gas is added to the oxygen containing gas during processing to dope the formed silicon oxide with fluorine or chlorine (e.g., about 1 atomic % fluorine). In one example, a silicon oxide film is formed by a rapid thermal oxidation process that uses lamp(s) to quickly heat a substrate surface to form an oxidized layer. In one example, the rapid thermal oxidation of a silicon substrate includes flowing the oxygen and hydrogen gases (e.g., O₂+H₂), for example, at a high enough flow rate to achieve a process pressure of between about 0.5-50 Torr and mixture to form an H₂ concentration over the surface of the substrate of about 1-13%. In this example, the processing temperature may be between about 800-1000° C. for between about 5-90 seconds to form a SiO₂ dielectric film of a desired thickness, as discussed above.

In another embodiment of a process performed at box 306, the interface layer 221 film formation process comprises depositing a silicon oxide containing film using a PECVD deposition process. In one example, the interface layer 221 is formed by flowing TEOS at a flow rate of 185 sccm, a helium flow rate of 50 sccm, an oxygen flow rate of 3500 sccm to achieve a pressure of about 0.85 Torr and providing 1150 W of 13.56 MHz RF power and a substrate support temperature of 430° C. In one embodiment, PECVD process may include introducing a fluorine (F₂), or a chlorine (Cl₂), containing gas to dope the formed silicon oxide film with a percentage of fluorine or chlorine (e.g., about 1 atomic % fluorine).

In another embodiment of a process performed at box 306, the interface layer 221 film formation process comprises depositing an aluminum oxide containing film using a PECVD deposition process. In one example, the interface layer 221 is formed by flowing trimethylaluminum (TMA) at a flow rate of 20 sccm per liter of chamber volume, flowing an oxygen bearing gas (e.g., oxygen (O₂) or nitrous oxide N₂O) at a flow rate of 50 sccm per liter of chamber volume, to achieve a pressure of about 500 mTorr to about 10 Torr, providing about 2000 W to about 12,000 W of 13.56 MHz RF power and a maintaining the substrate support temperature to between about 175 and about 500° C. Due to the bonding structure of aluminum and oxygen in a deposited aluminum oxide film, the trapped negative charge in the formed layer can be varied by adjusting the temperature, processing pressure and RF plasma power.

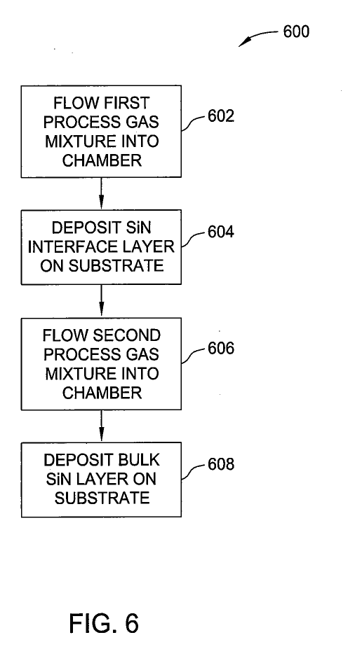

Next, at box 308, the substrate is exposed to a reactive gas containing RF plasma that is used to form a bulk layer 222, such as a multilayer hydrogenated SiN film on the interface layer 221 formed on the substrates 210. FIG. 6 illustrates an exemplary process sequence 600 used to form the passivation layer deposited in box 308 on a solar cell substrate 210. In one embodiment of the process sequence 600, at box 602, after the substrates 210 are positioned in another of the processing chambers 531-537 in the processing system 500, or, alternately, the same processing chamber used to form one or more of the prior steps, a process gas mixture is flowed into the chamber. The process gas mixture includes a precursor gas mixture and a hydrogen gas (H₂) diluent. The hydrogen gas diluent may have a flow rate as high as approximately two times the flow rate of the precursor gas mixture. The precursor gas mixture may be a combination of silane (SiH₄) and nitrogen (N₂), silane and ammonia (NH₃), or silane, ammonia, and nitrogen. In one example, flow rates for a process gas mixture containing silane, ammonia, and hydrogen may be 3.5 sccm, 50 sccm, and 80 sccm, per liter of chamber volume, respectively. Flow rates for a process gas mixture containing silane, ammonia, nitrogen, and hydrogen may be 5 sccm, 16 sccm, 40 sccm, and 80 sccm, per liter of chamber volume, respectively. The substrate support 430 temperature is generally maintained at a temperature of about 390° C. during this process step.

Next, at box 604, a plasma is then generated in the processing chamber to deposit a SiN layer on the substrates 210, wherein the SiN layer is suitable for use as a combined ARC and passivation layer for a solar cell. Namely, the SiN layer so deposited has a mass density of between about 2.6 and 2.8 g/cm³, a refractive index of between about 2.0 and 2.2, and a hydrogen concentration of between about 5 atomic percent and 15 atomic percent. In one embodiment, a chamber pressure of 1.5 Torr may be maintained in the chamber and an RF power intensity of 0.74 W/cm² at a frequency of 13.56 MHz is applied to the showerhead 410 of the processing chamber 400 to generate a plasma for a period of time of about 9 seconds, while the first process gas mixture is delivered to the processing volume 406.

Next, at box 606, a flow of the first process gas mixture is stopped, and a second process gas mixture is delivered into the chamber. In one example, the second process gas mixture may contain 5.5 sccm of silane (SiH₄), 16 sccm of ammonia (NH₃), and 40 sccm of nitrogen (N₂), per liter of chamber volume. In one embodiment, the plasma created during the processes performed in box 604 is extinguished in the processing chamber and the flow of the first process gas mixture is stopped, before the second process gas mixture is introduced into the processing chamber. In one embodiment, the process “break” performed at box 606 lasts about 2 seconds. In this case, the first process gas mixture may be substantially purged from the chamber before the second process gas mixture is flowed into the chamber. The substrate support 430 temperature is generally maintained at a temperature of about 390° C.

Finally, at box 608, a bulk SiN layer is deposited on the interface layer to form a dual stack SiN ARC/passivation layer on the substrates 210. In this way, the majority of the SiN passivation layer may be deposited by a substantially faster process without affecting the quality of solar cell passivation. If the plasma is extinguished in the chamber prior to the introduction of the second process gas mixture, then plasma is re-ignited to enable deposition of the bulk SiN layer. In one embodiment of the process 608, a chamber pressure of 1.5 Torr may be maintained in the processing chamber and an RF power intensity of 0.74 W/cm² at a frequency of 13.56 MHz is applied to the showerhead 410 of the processing chamber 400 to generate a plasma for a period of time of about 15 seconds, while the second process gas mixture is delivered to the processing volume 406.

While the foregoing is directed to embodiments of the present invention, other and further embodiments of the invention may be devised without departing from the basic scope thereof, and the scope thereof is determined by the claims that follow.

1. A method of forming at least a portion of a solar cell device, comprising:
forming a first layer having a negative charge over a surface of a p-type doped region formed in a solar cell substrate; and
forming a bulk layer over the first layer.

2. The method of claim 1, wherein the formed bulk layer has a net positive charge.

3. The method of claim 2, wherein the amount of net negative charge present in the first layer is greater than or equal to the amount of net positive charge in the bulk layer.

4. The method of claim 2, wherein the bulk layer comprises silicon and nitrogen.

5. The method of claim 1, wherein the amount of net negative charge present in the first layer is adapted to achieve a charge density of greater than 1×10¹² Coulombs/cm² at the surface of the solar cell substrate.

6. The method of claim 1, further comprising:
exposing a surface of the p-type doped region formed on the solar cell substrate to a reactive gas comprising nitrogen, fluorine or hydrogen prior to forming the first layer; and
exposing the surface of the p-type doped region to an RF plasma prior to forming the first layer to remove at least a portion of a dead region disposed on the surface.

7. The method of claim 6, wherein exposing the surface to a reactive gas and exposing the surface to an RF plasma each further comprise:
positioning two or more of the solar cell substrates in a planar array on a substrate carrier;
positioning the two or more solar cell substrates and the substrate carrier in a processing region of the processing chamber; and then
exposing the surface to the reactive gas and exposing the surface to the RF plasma on all of the two or more solar cell substrates simultaneously using a capacitively coupled plasma generated over the surfaces.

8. The method of claim 1, wherein forming the first layer comprises:
generating an RF plasma comprising a fluorine containing gas or a chlorine containing gas to deposit the first layer on the surface.

9. The method of claim 1, wherein forming the interface layer further comprises:
positioning two or more of the solar cell substrates in a planar array on a substrate carrier;
positioning the two or more solar cell substrates and the substrate carrier in a processing region of a plasma processing chamber; and then
forming the first layer on all of the two or more solar cell substrates simultaneously using a capacitively coupled plasma generated over the surfaces.

10. The method of claim 1, wherein forming the first layer comprises forming a layer comprising silicon oxide (SiₓO_{y}), silicon oxynitride (SiON), silicon oxycarbonnitride (SiOCN), silicon oxycarbide (SiOC), titanium oxide (TiₓO_{y}), tantalum oxide (TaₓO_{y}), lanthanum oxide (LaₓO_{y}), hafnium oxide (HfₓO_{y}), titanium nitride (TiₓN_{y}), tantalum nitride (TaₓN_{y}), hafnium nitride (HfN), hafnium oxynitride (HfON), lanthanum nitride (LaN), lanthanum oxynitride (LaON), chlorinated silicon nitride (SiₓN_{y}:Cl), chlorinated silicon oxide (SiₓO_{y}:Cl), fluorinated silicon oxide (SiₓO_{y}:F), fluorinated silicon nitride (SiₓN_{y}:F), amorphous silicon, amorphous silicon carbide or aluminum oxide (Al₂O₃).

11. The method of claim 1, further comprising:
positioning the solar cell substrate in a processing region of a processing chamber;
flowing a first process gas mixture into the processing region;
generating plasma in the processing region;
depositing a first silicon nitride-containing layer on the first layer;
stopping the flow of the first process gas mixture;
flowing a second process gas mixture into the processing chamber; and
depositing a second silicon nitride-containing layer on the first silicon nitride-containing layer.

12. The method of claim 1, wherein forming the first layer further comprises:
positioning the solar cell substrate in a processing region of a processing chamber; and
flowing a gas mixture comprising silane (SiH₄), nitrogen and a halogen gas into the processing region, wherein the halogen gas comprises fluorine or chlorine.

13. The method of claim 12, wherein forming the first layer further comprises:
forming a capacitively coupled plasma over a surface of the solar cell substrate by delivering RF power to an electrode disposed over the surface of the solar cell substrate.

14. A passivation layer structure formed in a solar cell device, comprising:
one or more p-type doped regions formed in a surface of a solar cell substrate;
a first layer having a net negative charge, wherein the first layer is disposed over the one or more p-type doped regions; and
a bulk layer disposed over the first layer, wherein the bulk layer has a net positive charge.

15. The passivation layer structure of claim 14, wherein the amount of net negative charge present in the first layer is greater than or equal to the amount of net positive charge in the bulk layer.

16. The passivation layer structure of claim 14, wherein the amount of net negative charge present in the first layer is adapted to achieve a charge density of greater than 1×10¹² Coulombs/cm² at the surface of the solar cell substrate.

17. The passivation layer structure of claim 14, wherein the bulk layer comprises silicon and nitrogen.

18. The passivation layer structure of claim 14, wherein the first layer comprises silicon oxide (SiₓO_{y}), silicon oxynitride (SiON), silicon oxycarbonnitride (SiOCN), silicon oxycarbide (SiOC), titanium oxide (TiₓO_{y}), tantalum oxide (TaₓO_{y}), lanthanum oxide (LaₓO_{y}), Hafnium oxide (HfₓO_{y}), titanium nitride (TiₓN_{y}), tantalum nitride (TaₓN_{y}), hafnium nitride (HfN), hafnium oxynitride (HfON), lanthanum nitride (LaN), lanthanum oxynitride (LaON), chlorinated silicon nitride (SiₓN_{y}:Cl), chlorinated silicon oxide (SiₓO_{y}:Cl), amorphous silicon, amorphous silicon carbide or aluminum oxide (Al₂O₃).

19. The passivation layer structure of claim 14, wherein:
the solar cell substrate comprises a n-type substrate having a first surface; and
the one or more p-type doped regions comprise a p-type layer disposed on the first surface of the n-type substrate.

20. A passivation layer structure formed in a solar cell device, comprising:
one or more p-type doped regions formed in a surface of a solar cell substrate;
a first layer disposed over the one or more p-type doped regions, wherein the first layer comprises fluorine or chlorine, and at least two elements selected from a list comprising oxygen, nitrogen, silicon and aluminum; and
a bulk layer disposed over the first layer, wherein the bulk layer has a net positive charge and comprises silicon and nitrogen.

21. The passivation layer structure of claim 20, wherein the first layer further comprises an amount of net negative charge that is greater than or equal to the amount of net positive charge in the bulk layer.

22. The passivation layer structure of claim 20, wherein the first layer further comprises an amount of net negative so as to achieve a charge density of greater than 1×10¹² Coulombs/cm² at the surface of the solar cell substrate.
